(19) United States
(12) Patent Application Publication
(10) Pub. No.: US 2025/0048700 A1
(43) Pub. Date: Feb. 6, 2025

(54) ULTRA-SHORT CHANNEL LENGTHS IN SIC MOS-BASED POWER DEVICES AND METHOD OF MAKING THE SAME

(71) Applicant: Purdue Research Foundation, West Lafayette, IN (US)

(72) Inventors: James Albert Cooper, Santa Fe, NM (US); Dallas Todd Morisette, Lafayette, IN (US)

(73) Assignee: Purdue Research Foundation, West Lafayette, IN (US)

(21) Appl. No.: 18/793,625

(22) Filed: Aug. 2, 2024

Related U.S. Application Data
(60) Provisional application No. 63/530,484, filed on Aug. 3, 2023.

(51) Int. Cl. H01L 29/10; H01L 23/64; H01L 29/16; H01L 29/423; H01L 29/78

(52) U.S. Cl. CPC H01L 29/1045; H01L 23/647; H01L 29/1083; H01L 29/1608; H01L 29/42364; H01L 29/7813

(57) ABSTRACT

A metal oxide semiconductor based power device in 4H-SiC semiconductor includes a semiconductor region, a drain electrode disposed adjacent a drain region and a source electrode disposed adjacent a source region which is disposed over a base region, and a gate electrode separated from the semiconductor region by silicon dioxide as a dielectric material. To avoid punchthrough, when the channel has a length of between i) about 0.5 μm and about 0.4 μm, ii) about 0.4 μm and about 0.3 μm, iii) about 0.3 μm and about 0.2 μm, or iv) about 0.2 μm and about 0.1 μm, the silicon dioxide has a corresponding thickness range of between i) about 5 nm to about 25 nm, ii) about 5 nm to about 20 nm, iii) about 5 nm to about 15 nm, or iv) about 5 nm to about 10 nm, respectively each base region at a predetermined doping profile.

### CROSS-REFERENCE TO RELATED APPLICATIONS

The present non-provisional patent application is related to and claims the priority benefit of U.S. Provisional Patent Application Ser. 63/530,484, filed Aug. 3, 2023, the contents of which are hereby incorporated by reference in its entirety into the present disclosure.

### STATEMENT REGARDING GOVERNMENT FUNDING

This invention was made with government support under DE-AR0001009 awarded by Department of Energy. The government has certain rights in the invention.

### TECHNICAL FIELD

The present disclosure generally relates to electronic switches, and in particular, to power devices with ultra-short channel lengths having ultra-low specific on-resistance.

### BACKGROUND

This section introduces aspects that may help facilitate a better understanding of the disclosure. Accordingly, these statements are to be read in this light and are not to be understood as admissions about what is or is not prior art.

For introductory purposes reference is made to FIGS. 1A and 1B. Referring to FIG. 1A, a power device 100, e.g., a power metal oxide semiconductor field effect transistor (MOSFET) is shown, as known to a person having ordinary skill in the art, including three terminals gate 102, drain 104, and source 106. In the off-state, the power device 100 blocks current passing between the drain 104 and source 106 up to its maximum rated voltage while allowing only a negligible leakage current to flow. In the normal on-state, the power device 100 permits a high current to flow between the drain 104 and source 106, limited by the load resistance of the circuit to which it is connected and the on-resistance of the power device 100. In either case the resulting power dissipation in the device remains low enough to prevent thermal damage to the device. In the power device 100 and many other power semiconductor devices, the on-state current is controlled by a metal-oxide-semiconductor (MOS) structure. This structure provides a high input impedance at the gate 102 that is desirable for circuit design considerations (i.e., improvement over bipolar devices requiring continuous electrical current to activate the device, i.e., to turn it on). Examples of MOS-controlled devices include the power MOS field effect transistors (MOSFETs, e.g., silicon carbide MOSFET (SIC MOSFET)), insulated gate bipolar transistors (IGBTs), and MOS-controlled thyristors (MCTs).

Referring to FIG. 1B, an electronic switching system 150 is shown with the power device 100 of FIG. 1A shown as being coupled to a load 152. The load 152 includes a load resistor 154, which as discussed above limits the current passing through the power device 100 (shown as I_{DS}) when in the on state. In other applications the load may be an inductive load such as an electric motor, or a more sophisticated load with a complex impedance that may be frequency dependent. When the power device 100 is in the on state, a channel is created (described below), allowing current to pass from the drain 104 to the source 106. The power device 100 is fully on when sufficient voltage is applied to the gate such that

V_{GS}>V_{T}, where
V_{GS} is the voltage between the gate 102 and the source 106 terminals, and
V_{T}r is a threshold voltage which depends on the power device 100 and is the threshold value of
V_{GS} above which the power device 100 begins to conduct load current when the drain-to-source voltage Vds>0.

Specific on-resistance of a power device is the product of its resistance in the ON or conducting state and its area, measured in (Ω cm²) or (mΩ cm²). An example schematic of a typical SiC planar power MOSFET is shown in FIG. 2 and of a typical trench power MOSFET is shown in FIG. 3. Referring To FIG. 2, a cross sectional view of a metal-oxide-semiconductor (MOS) power device 200, and in particular a double-diffused or double-implanted MOS field effect transistor (DMOSFET), is shown. It should be appreciated that the term DMOSFET originated with double-diffused silicon. While diffusion is impractical in SiC and the above-referenced SiC power device of the present disclosure are formed by double implantation, the same acronym as the silicon device is used for SiC. The MOS power device 200 includes a drain electrode 202 (identified as “Drain Contact”) in electrical contact with a drain semiconductor region 204 (shown as “N+ Drain Region”) of a first conductivity type (N type shown, however the first conductivity type can be P type while a second conductivity type can be N type). The material of the drain semiconductor region 204 can be doped silicon carbide. The MOS Power device 200 also includes a drift semiconductor region 206 of the first conductivity type (shown as “N-Drift Region”, however the first conductivity type can be P type while the second conductivity type can be N type). The drift semiconductor region 206 is coupled to the drain semiconductor region 204. The material of the drift semiconductor region 206 can be doped silicon carbide. The MOS power device 200 further includes a base semiconductor region 208 of the second conductivity type (shown as “P Base”, however the second conductivity type can be N type while the first conductivity type can be P type). The base semiconductor region 208 is coupled to the drift semiconductor region 206 through the pn junction at the interface between these two regions. The material of the base semiconductor region 208 can be doped silicon carbide. The MOS power device 200 further includes a source semiconductor region 210 of the first conductivity type (shown as “N+ Source”, however the first conductivity type can be P type while the second conductivity type can be N type). The source semiconductor region 210 is coupled to the base semiconductor region 208 and isolated by the base semiconductor region 208 from the drift semiconductor region 206. The material of the source semiconductor region 210 can be doped silicon carbide. The MOS power device 200 further includes a source electrode 212 (shown as “Source Contact”) that is coupled to the source semiconductor region 210, making electrical contact therewith. The MOS power device 200 further includes a gate electrode 214 (shown simply as “Gate”) that is provided adjacent at least a portion of but isolated from i) the base semiconductor region 208, ii) the source semiconductor region 210, and iii) the drift semiconductor region 206 by a dielectric material 216. The drift semiconductor region 206 has a sufficient thickness and doping to withstand greater than e.g., 100 V (this value depends on the semiconductor material-in silicon the drift region may only be designed to withstand greater than 20-30 V; in SiC, the drift region typically withstands more than 400-500 V; and GaN is above 50-100 V) between the drain electrode 202 and the source electrode 212 when substantially no current is flowing through the drain electrode 202. The MOS power device 200 further includes a semiconductor region 218 of the second conductivity type (shown as “P+”, however the second conductivity type can be N type while the first conductivity type be P type). The semiconductor region 218 is coupled to the base semiconductor region 208. The material of the semiconductor region 218 can be doped silicon carbide. The MOS power device 200 further includes a base contact 220 (shown as “Base Contact”) that is coupled to the semiconductor region 218, making electrical contact therewith. It should be appreciated that other elements may also be present, for example, the MOS power device 200 may have a continuous overlayer of metal connecting multiple source electrodes 212 and base contacts 220 together but insulated from the gate electrode 214 by a dielectric layer (not shown).

Referring to FIG. 3, a cross sectional view of a MOS power device 300, and in particular a UMOSFET, is shown. The MOS power device 300 includes a drain electrode 302 (identified as “Drain Contact”) in electrical contact with a drain semiconductor region 304 (shown as “N+ Drain”) of a first conductivity type (N type shown, however the first conductivity type can be P type while a second conductivity type be N type). The material of the drain semiconductor region 304 can be doped silicon carbide. The MOS power device 300 also includes a drift semiconductor region 306 of the first conductivity type (shown as “N-Drift Region”, however the first conductivity type can be P type while the second conductivity type can be N type). The drift semiconductor region 306 is coupled to the drain semiconductor region 304. The material of the drift semiconductor region 306 can be doped silicon carbide. The MOS power device 300 further includes a base semiconductor region 308 of the second conductivity type (shown as “P Base”, however the second conductivity type can be N type while the first conductivity type can be P type). The base semiconductor region 308 is coupled to the drift semiconductor region 306 through the pn junction at the interface between these two regions. The material of the base semiconductor region 308 can be doped silicon carbide. The MOS power device 300 further includes a source semiconductor region 310 of the first conductivity type (shown as “N+ Source”, however the first conductivity type can be P type while the second conductivity type can be N type). The source semiconductor region 310 is coupled to the base semiconductor region 308 and isolated by the base semiconductor region 308 from the drift semiconductor region 306. The material of the source semiconductor region 310 can be doped silicon carbide. The MOS power device 300 further includes a source electrode 312 (shown as “Source Contact”) that is coupled to the source semiconductor region 310, making electrical contact therewith. The MOS power device 300 further includes a gate electrode 314 (shown simply as “Gate”) that is provided adjacent at least a portion of but isolated from i) the base semiconductor region 308, ii) the source semiconductor region 310, and iii) the drift semiconductor region 306 by a dielectric material 316. The dielectric material 316 has a thickness between 1 nm and 30 nm (or between 1 nm and 25 nm, or between 1 nm and 20 nm, or between 1 nm and 15 nm, or between 1 nm and 10 nm, or between 1 and 5 nm) multiplied by a correction factor defined as a ratio of dielectric permittivity of the dielectric material and the permittivity of silicon dioxide. The gate electrode 314 and the dielectric material 316 both are U-shaped, to be contrasted with the gate electrode 214 and the dielectric material 216 of the DMOSFET shown in FIG. 2. The drift semiconductor region 306 has a sufficient thickness and doping to withstand greater than e.g., 100 V (this value depends on the semiconductor material-in SiC, the drift region typically withstands more than 400-500 V) between the drain electrode 302 and the source electrode 312 when substantially no current is flowing through the drain electrode 302. The MOS power device 300 further includes a semiconductor region 318 of the second conductivity type (shown as “P+”, however the second conductivity type can be N type while the first conductivity type can be P type). The semiconductor region 318 is coupled to the base semiconductor region 308. The material of the semiconductor region 318 can be doped silicon carbide. The MOS power device 300 further includes a base contact 320 (shown as “Base Contact”) that is coupled to the semiconductor region 318, making electrical contact therewith.

In all SiC power MOS-based devices with blocking voltages equal to or below about 1200 V, the dominant component of internal resistance is the channel resistance, i.e. the resistance of the electron inversion layer formed at the interface between the oxide under the gate electrode and the p-type base layer. This inversion layer forms when the gate voltage is above a threshold voltage, and it provides a conducting path allowing electrons to flow from the n+ source to the n-drift region and n+ drain. The resistance of the inversion layer is proportional to the channel length L_{CH} measured between the n+ source on one side of the p base and the n-type region of the opposite side of the p base. To reduce the channel resistance, and hence the specific resistance of the power MOSFET, it is beneficial to reduce the channel length as much as possible.

However, a significant limit on the minimum usable channel length is punchthrough of the base region as the channel length is reduced. Punchthrough occurs in the OFF (or blocking) state of the MOSFET, further described below, when the depletion region of the base/drift region (or base/JFET region) junction extends through the base and merges with the depletion region of the source/base junction. When this condition occurs, a large electron current flows directly from source to drift region (or JFET region), and this current cannot be turned off by the gate.

Another limitation on the minimum usable channel length is drain induced barrier lowering (DIBL) in the on-state of the MOSFET. DIBL can cause high output conductance in the saturation region, leading to high saturation currents and therefore reduced short-circuit withstand time.

Therefore, there is an unmet need for a novel power device arrangement that improves the on-resistance without sacrificing the normal operational parameters such as threshold voltage, blocking voltage, i.e., which can avoid punchthrough.

### SUMMARY

A metal oxide semiconductor (MOS)-based power device in 4H-SiC semiconductor is disclosed. The MOS-based power device includes a semiconductor region, a drain electrode disposed adjacent a drain region and a source electrode disposed adjacent a source region, the source region disposed over a base region, and a gate electrode separated from the semiconductor region by one or more insulating dielectric material layers. A load current passing through the drain and source electrodes is controlled by an electric field induced by the gate electrode into the semiconductor region thereby forming a conductive channel. To avoid punchthrough, defined as depletion region of the pn junctions on either side of the base region reaching through the base region and merging thus allowing a substantial current flow through the source electrode when the device is in an off state: when the channel has a length of between about 0.5 μm and about 0.4 μm, the silicon dioxide has a corresponding thickness range of between about 5 nm to about 25 nm, and the base region has a first predetermined doping profile, when the channel has a length of between about 0.4 μm and about 0.3 μm, the silicon dioxide has a corresponding thickness range of between about 5 nm to about 20 nm, the base region has a second predetermined doping profile, when the channel has a length of between about 0.3 μm and about 0.2 μm, the silicon dioxide has a corresponding thickness range of between about 5 nm to about 15 nm, the base region has a third predetermined doping profile, and when the channel has a length of between about 0.2 μm and about 0.1 μm, the silicon dioxide has a corresponding thickness range of between about 5 nm to about 10 nm, the base region has a fourth predetermined doping profile. The first, second, third and fourth predetermined doping profiles each with its associated channel length provides a near minimum specific on resistance for a prescribed blocking voltage.

In the above MOS-based power device, when the channel has a length of between about 0.5 μm and about 0.4 μm, the silicon dioxide has a corresponding thickness range of between about 5 nm to about 20 nm.

In the above MOS-based power device, when the channel has a length of between about 0.5 μm and about 0.4 μm, the silicon dioxide has a corresponding thickness range of between about 5 nm to about 15 nm.

In the above MOS-based power device, when the channel has a length of between about 0.5 μm and about 0.4 μm, the silicon dioxide has a corresponding thickness range of between about 5 nm to about 10 nm.

In the above MOS-based power device, when the channel has a length of between about 0.4 μm and about 0.3 μm, the silicon dioxide has a corresponding thickness range of between about 5 nm to about 15 nm.

In the above MOS-based power device, when the channel has a length of between about 0.4 μm and about 0.3 μm, the silicon dioxide has a corresponding thickness range of between about 5 nm to about 10 nm.

In the above MOS-based power device, when the channel has a length of between about 0.3 μm and about 0.2 μm, the silicon dioxide has a corresponding thickness range of between about 5 nm to about 10 nm.

### BRIEF DESCRIPTION OF DRAWINGS

The patent or application file contains at least one drawing executed in color. Copies of this patent or patent application publication with color drawing(s) will be provided by the Office upon request and payment of the necessary fee.

FIG. 1A is a symbolic representation of a power device, e.g., a power metal oxide semiconductor field effect transistor (MOSFET).

FIG. 1B is a schematic of the MOSFET of FIG. 1A with a load.

FIG. 2 is a cross sectional view of a MOS power device, and in particular a double-diffused or double-implanted MOS field effect transistor (DMOSFET).

FIG. 3 is a cross sectional view of a UMOSFET.

FIG. 4 is simulation results of a planar power MOSFET device depicting various structures, with dimensions provided only as a non-limiting example.

FIG. 5 is a partial reproduction of FIG. 4 and a graph of base region p-type doping concentration vs. depth in μm is shown in FIG. 4 across a section identified as A-A. This figure shows several different doping profile options that were simulated.

FIGS. 6-8 are simulation results showing electric field profile at punchthrough (FIG. 6), electron current density at punchthrough (FIG. 7), and hole current density at punchthrough (FIG. 8). In each case the channel length was 0.25 μm and the long doping profile from FIG. 5 was used.

FIGS. 9-11 are simulation results showing electric field profile at avalanche breakdown (FIG. 9), electron current density at avalanche breakdown (FIG. 10), and hole current density at avalanche breakdown (FIG. 11) for the doping profile shown in FIG. 5. In each case the channel length was 0.25 μm and the short1 doping profile from FIG. 5 was used.

FIG. 12 provides graphs of breakdown voltages in V vs. channel length in μm and specific on-resistance in *mΩ·cm² vs. channel length in μm, depicting different concentration base doping profiles, labeled “long”, “short1”, “short2”, “short3”, and “short4”.

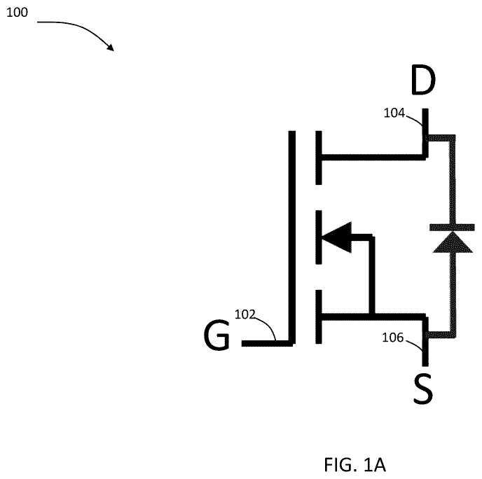

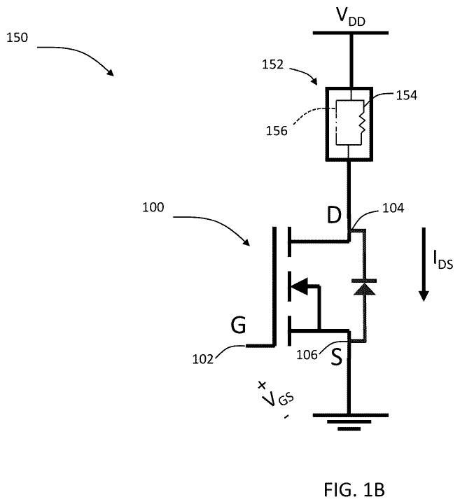

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 15%, within 10%, within 5%, or within 1% of a stated value or of a stated limit of a range.

In the present disclosure, the term “substantially” can allow for a degree of variability in a value or range, for example, within 85%, within 90%, within 95%, or within 99% of a stated value or of a stated limit of a range.

A novel power device arrangement is provided herein that improves the on-resistance without sacrificing normal operational parameters such as threshold voltage and blocking voltage and without increasing cell area or overall device area. Specifically the novel arrangement avoids punchthrough for ultra-short channel lengths used for ultra-low on-resistance metal oxide semiconductor (MOS)-based power devices.

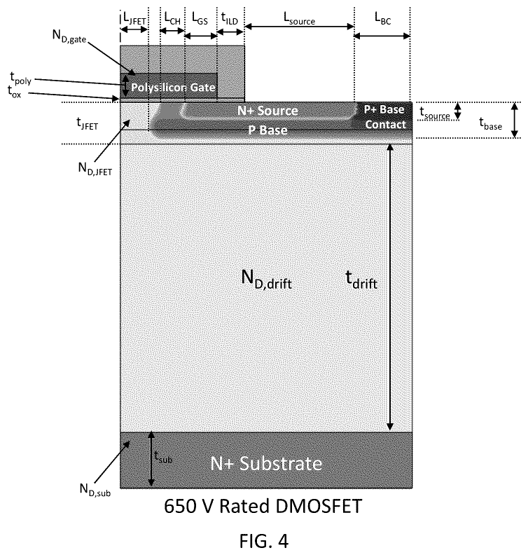

To demonstrate this phenomenon, reference is made to FIG. 4 in which is a simulation result from a power MOSFET device, in particular a DMOSFET, depicting various structures, with dimensions provided only as a non-limiting example. The device provides a MOSFET structure with a polysilicon gate disposed under an interlayer dielectric (ILD) over the source region, the base region, and the JFET region. Various structures, such as the JFET length (L_{JFET}), channel length (L_{CH}), gate-to-source length (L_{GS}), ILD thickness (t_{ILD}) which also describes a gate to source electrode gap, source length (L_{source}), base contact length (LBC), polysilicon gate thickness (t_{poly}), oxide thickness (tₒₓ), thickness of the JFET region plus an optional current spreading layer (t_{JFET}), thickness disposed between the drift region and the base region, and thickness of the substrate (t_{sub}), which are all known to a person having ordinary skill in the art are shown in FIG. 4 along with example values shown in Table 1 for each such parameter.

TABLE 1
Example values for parameters shown in FIG. 4

| Simulation Parameters | | |
|---|---|---|
| L_{JFET} | 0.75 | μm |
| L_{CH} | Varied | |
| L_{GS} | 0.5 | μm |
| L_{source} | 2.0 | μm |
| L_{BC} | 1.0 | μm |
| t_{ILD} | 0.5 | μm |
| t_{poly} | 0.5 | μm |
| tₒₓ | Varied | |
| t_{JFET} | 0.75 | μm |
| t_{drift} | 5.2 | μm |
| t_{sub} | (not important to the simulation, | |
| | but 1.0 μm was simulated) | |
| N_{D, JFET} | 1 × 10¹⁷ | cm⁻³ |
| N_{D, drift} | 2.5 × 10¹⁶ | cm⁻³ |
| N_{D, sub} | 1 × 10¹⁹ | cm⁻³ |
| N_{D, gate} | 1 × 10²⁰ | cm⁻³ |
| t_{base} | 0.6 | μm |
| t_{source} | 0.3 | μm |

The gate oxide is SiO₂.

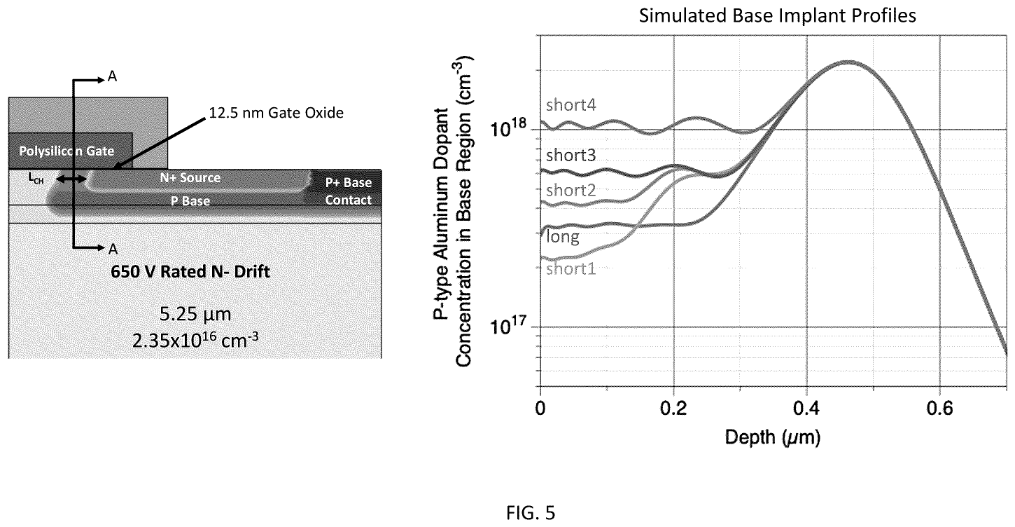

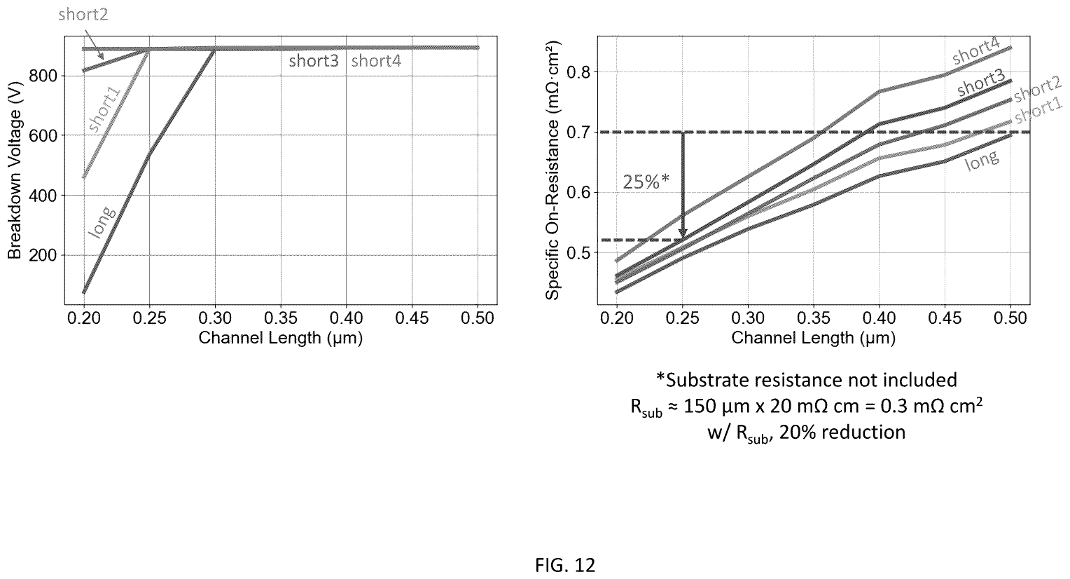

Referring to FIG. 5, an example base region doping profile (i.e., doping concentration in cm⁻³ vs. depth in μm) is provided for some of the regions of the structure depicted in FIG. 4, specifically across a section A-A shown in FIG. 5. This doping profile is an example of the profiles typically used in SiC power MOSFETs, as is known to a person having ordinary skill in the art. Five different configurations are provided in the base doping profile shown in FIG. 5, including long, short1, short2, short3, and short4. The long profile represents a typical current state-of-the-art DMOSET retrograde base doping profile, with a near-surface doping chosen to give a low threshold voltage for the MOSFET, and the higher doping below the surface designed to prevent punchthrough at the bottom of the base in the blocking state. Those labeled short1 through short4 represent options more appropriate for a short channel DMOSFET. These Al implant profiles are the sum of various sequential ion implantation profiles calculated based on the Janson model (M. S. Janson et al., “Ion implantation range distributions in silicon carbide”, J. Appl. Phys., vol. 93, no. 11, pp. 8903-8909, 2003). The higher doping concentration in the near surface region of the “short” profiles reduces the penetration of the depletion region from the JFET side of the base region as the drain voltage is increased. When this depletion region significantly overlaps with the depletion region from the source side of the base region, punchthrough occurs. For a sufficiently high near surface base doping concentration, punchthrough will be suppressed, and the off-state drain voltage will be limited by avalanche breakdown rather than punchthrough. Referring to FIG. 12, further discussed below, a graph of blocking voltage in V vs. channel length in μm for the doping profiles of FIG. 5 is provided, using the parameter values in Table 1. The blocking voltage represents an important parameter when the device is off. The channel length was varied from about 0.2 μm to about 0.5 μm. As it is clear from FIG. 12, the blocking voltage degrades quickly when the channel length has reduced to below 0.3 μm in this example if the long profile from FIG. 5 is used. Thus, from FIG. 12 it can be deduced for the parameters shown in Table 1 and the long doping profile shown in FIG. 5, the minimum channel length is about 0.3 μm before the structure exhibits punchthrough.

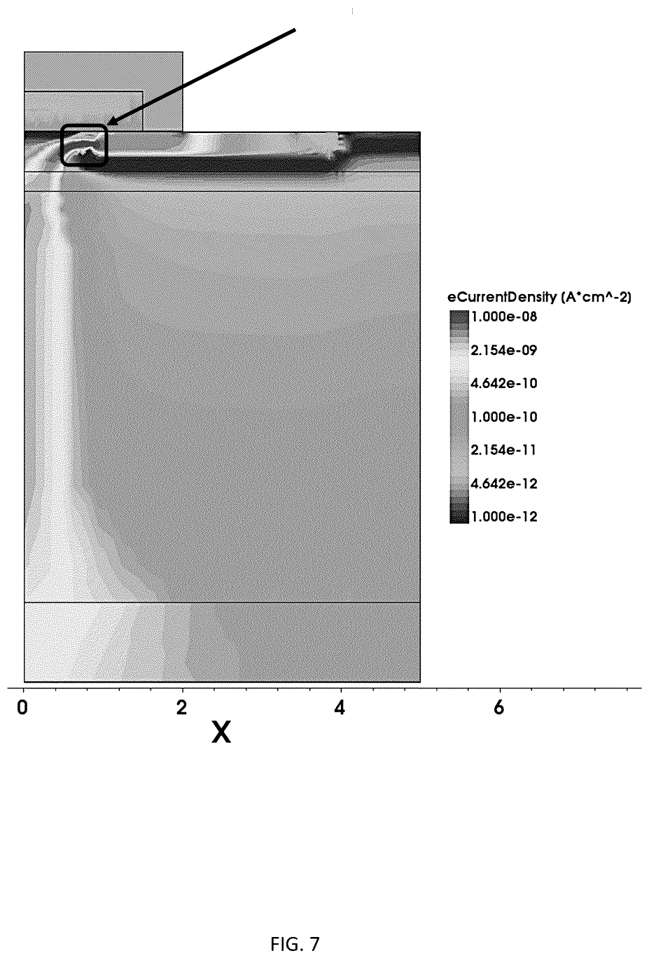

In each case presented in FIG. 12, the oxide thickness tₒₓ is 12.5 μm. As illustrated in FIG. 7, which shows a contour plot of simulated electron current density throughout a device with a 0.25 μm channel length, the “long” doping profile from FIG. 5, and with an applied drain voltage near breakdown, the degradation in blocking voltage for channel lengths below about 0.3 μm is due to punchthrough of the drain depletion region through the portion of the p base between the JFET region and the source as the channel length is reduced. This is evidenced in FIG. 7, discussed further below, by the continuous electron current flow from the source, through the base region well below the oxide-semiconductor interface, through the drift region and into the drain contact.

Channel length can be beneficially shortened by reducing the oxide thickness t_{OX} and the on-state gate voltage V_{GS} in such a way as to maintain a specified oxide field E_{REL}. The value of E_{REL} is chosen to achieve the desired long-term reliability of the MOSFET at the rated drain voltage and maximum rated junction temperature. The relationship is given by:

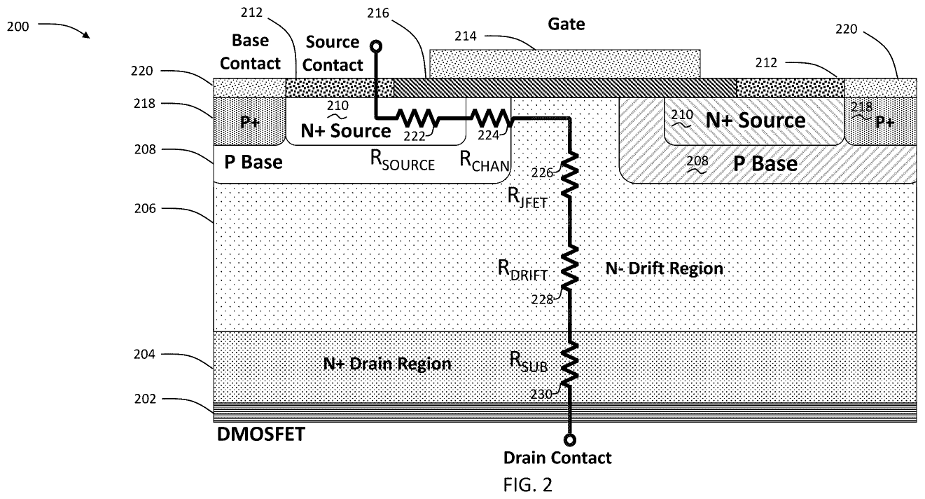

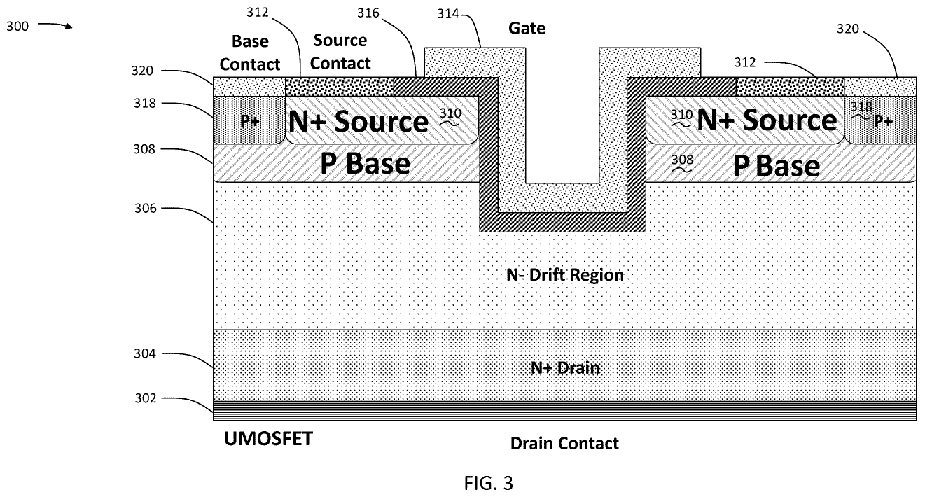

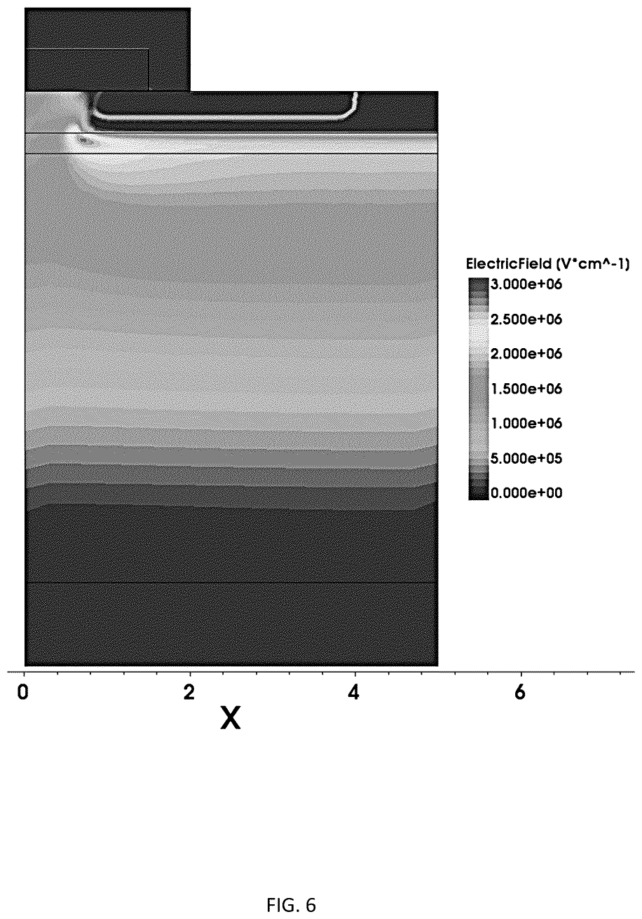

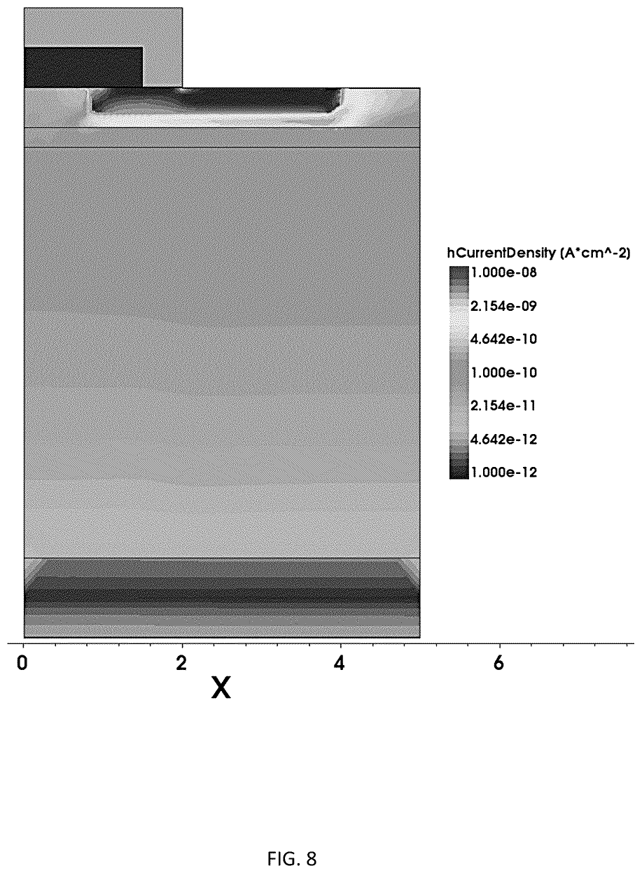

V_{GS}=E_{REL}t_{OX}+ϕ_{GS}+2ψ_{F} (1)

where ϕ_{GS} is the gate-to-semiconductor work function, and
φ_{F} is the Fermi potential of the semiconductor base region at the surface. We performed 2-D numerical simulations of the planar MOSFET of FIG. 2 and, as discussed above, we find there is a lower limit to the channel length before punchthrough of the base occurs below the surface. FIGS. 6-8 show the electric field magnitude, electron current density, and hole current density at the onset of punchthrough for a channel length of 0.25 μm and an oxide thickness of 12.5 nm with the gate and base grounded and the drain at 490 V_{GS}. Specifically, FIG. 6 (electric field profile at punchthrough) shows the highest electric field occurs at the interior corner of the grounded base, FIG. 7 (electron current density at punchthrough) shows electron current streaming from the n+ source through the narrowest portion of the base and down to the positive drain terminal, and FIG. 8 (hole current density at punchthrough) shows minimal hole current. It should be understood that if the current had been due to avalanche breakdown instead of punchthrough, we would see electron current flowing only downward from the high-field point and hole current flowing laterally from the high-field point, across the base and into the base contact at the right. A closer look at the electron current path in FIG. 7 reveals that punchthrough is occurring below the surface. Thus the surface channel remains turned off due to improved gate control provided by the thin oxide, but the doping immediately below the surface of the base is insufficient to prevent punchthrough in this region. It occurred to the present inventors that it might be possible to prevent sub-surface punchthrough by increasing the doping of the p-base in the region closer to the surface where punchthrough is taking place.

When the doping level of the base at the oxide/semiconductor interface is increased, this causes an undesirable increase in the threshold voltage of the MOSFET. In order to adjust the threshold voltage to a desired value while still preventing punchthrough, the inventors propose to include a threshold adjust implant in the upper portion of the base. To reduce the threshold voltage, this implant will be of the opposite doping polarity from the base region below, e.g. an N-type implant if the base is P-type, or a P-type implant if the base is N-type. To increase the threshold voltage, this implant will be of the same doping polarity as the base region below, e.g. an N-type implant if the base is N-type, or a P-type implant if the base is P-type. The implant will be very shallow in depth, extending from the surface only a small fraction of the source region thickness. Typical N-type dopants used in SiC are nitrogen (N) or phosphorus (P). Typical P-type dopants used in SiC are aluminum (Al) or boron (B).

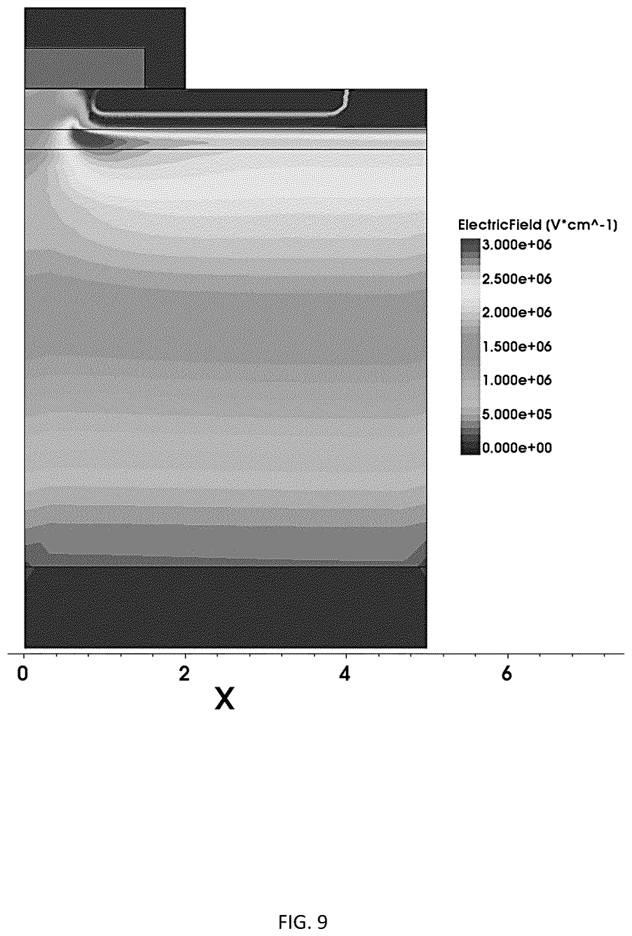

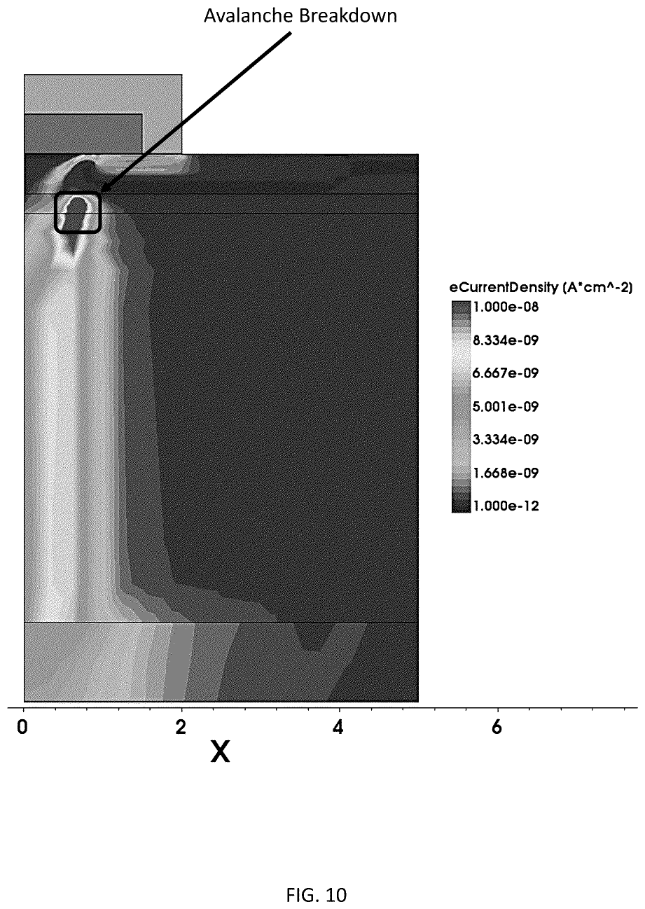

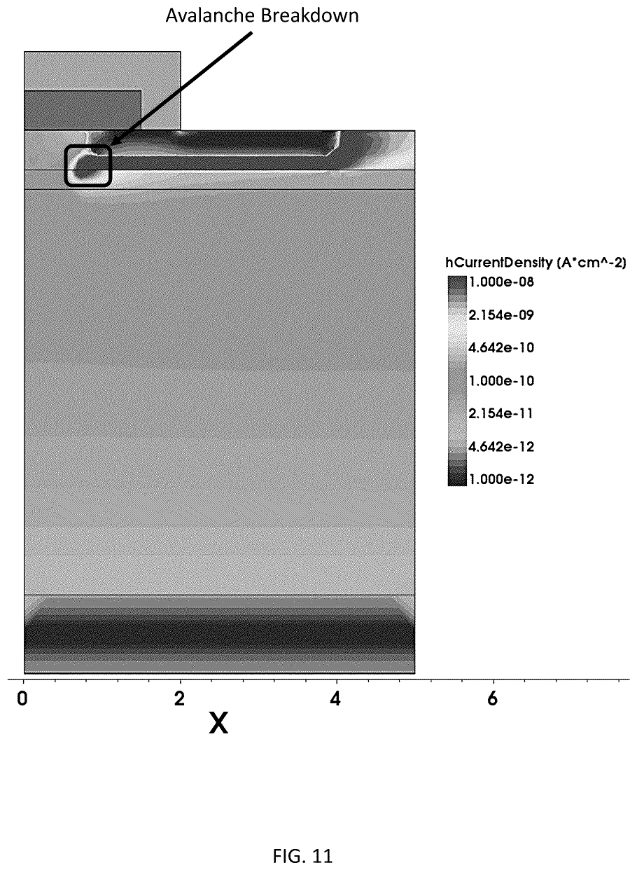

The structure of simulations of FIGS. 6-8 (i.e., channel length of 0.25 μm and an oxide thickness of 12.5 nm) was next simulated using the base doping profile “short1”, and the results are shown in FIGS. 9-11, which similar to FIGS. 6-8 provide electric field profile at breakdown, electron current at breakdown, and hole current at breakdown. With these higher doping profiles, the maximum drain voltage is now increased from the low value of 490 V in FIGS. 6-8 to a more desirable value of 748 V, and the current flow is now due to avalanche breakdown rather than punchthrough. Specifically, this change can be seen in FIGS. 10 and 11, where the electron current flows from the high-field location only downward to the drain and an equal hole current flows from the high-field location laterally across the base to the base contact. This is the unmistakable signature of avalanche breakdown.

Referring back to FIG. 5 and further to FIG. 12 which provides graphs of breakdown voltages in V vs. channel length in μm and specific on-resistance in *mΩ·cm² vs. channel length in μm, we have also investigated other base doping profiles with increased near-surface doping concentrations, labeled “short1”, “short2”, and “short4”, discussed above, and these allow us to use successively shorter channels that further reduce the specific on-resistance. Thus, to prevent punchthrough and drain induced barrier lowering (DIBL) from occurring at the surface one can use one or more of i) higher doping in the base regions of the short-channel SiC power MOSFETs, and ii) the use of thin gate oxides and correspondingly reduced drive voltages; and to prevent punchthrough from occurring below the surface one can use higher doping in the base regions of the short-channel SiC power MOSFETs. The benefits are reduced channel length, leading to a reduced resistance-area product that allows manufacturers to place more transistor die on a wafer, thereby reducing cost without compromising performance, ruggedness, or reliability. This approach can be applied to a variety of MOS-based power devices in SiC, including (but not limited to) planar MOSFETs, trench MOSFETs, lateral MOSFETs, planar and trench superjunction MOSFETs, tri-gate MOSFETs, superjunction tri-gate MOSFETs, planar and trench insulated-gate bipolar transistors (IGBTs), and planar and trench MOS-controlled thyristors (MCTs).

Additionally, disclosed herein is a method of adjusting the threshold voltage to a desired value while still preventing punchthrough, which includes establishing a threshold adjust implant in the upper portion of the base. To reduce the threshold voltage, this implant will be of the opposite doping polarity from the base region below, e.g. an N-type implant if the base is P-type, or a P-type implant if the base is N-type. To increase the threshold voltage, this implant will be of the same doping polarity as the base region below, e.g. an N-type implant if the base is N-type, or a P-type implant if the base is P-type. The implant will be very shallow in depth, extending from the surface only a small fraction of the source region thickness. Typical N-type dopants used in SiC are nitrogen (N) or phosphorus (P). Typical P-type dopants used in SiC are aluminum (Al) or boron (B). Thus, to prevent punchthrough and DIBL from occurring at the surface one or more of the following methods can be used: i) establishing a higher doping in the base regions of the short-channel SiC power MOSFETs, and ii) providing a thin gate oxides and correspondingly reducing drive voltages; and to prevent punchthrough from occurring below the surface the following method can be used: establishing a higher doping in the base regions of the short-channel SiC power MOSFETs.

Those having ordinary skill in the art will recognize that numerous modifications can be made to the specific implementations described above. The implementations should not be limited to the particular limitations described. Other implementations may be possible. Those with ordinary skill in the art will also recognize that similar implementations can be applied in other wide bandgap semiconductors such as, but not limited to, gallium nitride (GaN) and its alloys and ternary compounds.

1. A metal oxide semiconductor (MOS)-based power device in 4H-SiC semiconductor, comprising:
a semiconductor region;
a drain electrode disposed adjacent a drain region and a source electrode disposed adjacent a source region, the source region disposed over a base region;
a gate electrode separated from the semiconductor region by silicon dioxide as a dielectric material, wherein a load current passing through the drain and source electrodes is controlled by an electric field induced by the gate electrode into the semiconductor region thereby forming a conductive channel;
wherein to avoid punchthrough, defined as depletion region of the pn junctions on either side of the base region reaching through the base region and merging thus allowing a substantial current flow through the source electrode when the device is in an off state:
when the channel has a length of between about 0.5 μm and about 0.4 μm, the silicon dioxide has a corresponding thickness range of between about 5 nm to about 25 nm, and the base region has a first predetermined doping profile,
when the channel has a length of between about 0.4 μm and about 0.3 μm, the silicon dioxide has a corresponding thickness range of between about 5 nm to about 20 nm, the base region has a second predetermined doping profile,
when the channel has a length of between about 0.3 μm and about 0.2 μm, the silicon dioxide has a corresponding thickness range of between about 5 nm to about 15 nm, the base region has a third predetermined doping profile, and
when the channel has a length of between about 0.2 μm and about 0.1 μm, the silicon dioxide has a corresponding thickness range of between about 5 nm to about 10 nm, the base region has a fourth predetermined doping profile,
such that the first, second, third and fourth predetermined doping profiles each with its associated channel length provides a near minimum specific on resistance for a prescribed blocking voltage.

2. The MOS-based power device of claim 1, wherein material of the drain, source, and gate electrodes comprises one or more of copper, silver, gold, carbon, graphite, nickel, titanium, aluminum, polysilicon, and graphene.

3. The MOS-based power device of claim 1, wherein the semiconductor region comprises an N-type conductivity type and a P-type conductivity type.

4. The MOS-based power device of claim 1, wherein the semiconductor region comprises a first semiconductor region, a second semiconductor region, and a third semiconductor region.

5. The MOS-based power device of claim 4, wherein the first semiconductor region has a dopant level higher than a dopant level of the second semiconductor region.

6. The MOS-based power device of claim 5, wherein the third semiconductor region has a dopant level higher than a dopant level of the second semiconductor region.

7. The MOS-based power device of claim 1, wherein the electric field induced by the gate electrode is based on application of a gate-to-source voltage (V_{GS}) established based on thickness of the dielectric material.

8. The MOS-based power device of claim 7, wherein V_{GS} is expressed as a function of the thickness of the dielectric material based on:
Eᵢₙₛ=(V_{GS}−φ_{GS}−2ψ_{F})/tᵢₙₛ
Eᵢₙₛ is the electric field in the dielectric material induced by the gate electrode,
φ_{GS} is a work function difference between the gate material and the semiconductor in the channel region in volts,
ψ_{F} is the bulk Fermi potential of the semiconductor material in the channel region (determined by its doping) in volts, and
tᵢₙₛ is the thickness of the dielectric material between the gate and the semiconductor in centimeters.

9. The MOS-based power device of claim 1, wherein the device is a planar MOS field effect transistor (MOSFET), a DMOSFET, a trench MOSFET, a lateral MOSFET, a planar superjunction MOSFET, a trench superjunction MOSFET, a planar insulated-gate bipolar transistor, a trench insulated-gate bipolar transistor, a planar MOS-controlled thyristor, or a trench MOS-controlled thyristor.

10. The MOS-based power device of claim 1, wherein when the channel has a length of between about 0.5 μm and about 0.4 μm, the silicon dioxide has a corresponding thickness range of between about 5 nm to about 20 nm.

11. The MOS-based power device of claim 1, wherein when the channel has a length of between about 0.5 μm and about 0.4 μm, the silicon dioxide has a corresponding thickness range of between about 5 nm to about 15 nm.

12. The MOS-based power device of claim 1, wherein when the channel has a length of between about 0.5 μm and about 0.4 μm, the silicon dioxide has a corresponding thickness range of between about 5 nm to about 10 nm.

13. The MOS-based power device of claim 1, wherein when the channel has a length of between about 0.4 μm and about 0.3 μm, the silicon dioxide has a corresponding thickness range of between about 5 nm to about 15 nm.

14. The MOS-based power device of claim 1, wherein when the channel has a length of between about 0.4 μm and about 0.3 μm, the silicon dioxide has a corresponding thickness range of between about 5 nm to about 10 nm.

15. The MOS-based power device of claim 1, wherein when the channel has a length of between about 0.3 μm and about 0.2 μm, the silicon dioxide has a corresponding thickness range of between about 5 nm to about 10 nm.
